(19) United States
(12) Patent Application Publication
(10) Pub. No.: US 2021/0011333 A1
(43) Pub. Date: Jan. 14, 2021

(54) METHOD FOR MANUFACTURING DISPLAY PANEL AND DISPLAY PANEL THEREOF

(71) Applicant: HKC CORPORATION LIMITED, Shenzhen (CN)

(72) Inventor: Beizhou HUANG, Shenzhen (CN)

(21) Appl. No.: 16/981,408

(22) PCT Filed: Dec. 17, 2018
(86) PCT No.: PCT/CN2018/121461

§ 371 Date: Sep. 16, 2020

(30) Foreign Application Priority Data
May 22, 2018 (CN) 201810495790.3

(51) Int. Cl. G02F 1/1335

(52) U.S. Cl. CPC G02F 1/133516; G02F 1/133512

(57) ABSTRACT

Disclosed are a method for manufacturing a display panel and a display panel, the method including: providing a substrate, at least one exposure alignment identifier being disposed on the substrate; forming a color filter layer on a side of the exposure alignment identifier away from the substrate, the color filter layer including an identification thickened layer covering the exposure alignment identifier, the identification thickened layer having the same shape and the same size as the exposure alignment identifier; forming a black photoresist layer on a side of the color filter layer away from the substrate; and performing exposure alignment by the exposure alignment identifier and the identification thickened layer.

### CROSS-REFERENCE TO RELATED APPLICATIONS

The present application is the National Stage of International Application No. PCT/CN2018/121461, filed on Dec. 17, 2018, which claims the benefit of Chinese Patent Application No. 201810495790.3, filed on May 22, 2018 with the National Intellectual Property Administration and entitled “Method for Manufacturing Display Panel”, the entirety of which is hereby incorporated herein by reference.

### FIELD

The present disclosure relates to the field of display technologies, and more particularly relates to a method for manufacturing a display panel and a display panel thereof.

### BACKGROUND

With the development of display technology, black matrix is usually integrated on the array substrate-namely the Black Matrix on Array (BOA) technology, to avoid the problem of light shielding area mismatch caused by the misalignment of the upper and lower substrates. Meanwhile, in the manufacturing process of the display device, an exposure alignment identifier is usually disposed to improve the alignment accuracy in the process.

However, since the black light shielding layer forming the black matrix with material having a high optical density (OD), the coating of the material may interfere with the recognition of the exposure alignment identifier, thereby causing the inaccurate alignment of the exposure machine; if black light shielding material with lower OD is used, the difficulty of recognition of the exposure alignment identifier may be reduced, while the light shielding effect of the black matrix is seriously affected.

### SUMMARY

The embodiments of the present disclosure provide a method for manufacturing a display panel, which enables accurate recognition of an exposure alignment identifier without affecting light shielding effect of a black matrix.

The embodiments of the present disclosure provide a method for manufacturing a display panel, and the method includes:

providing a substrate, at least one exposure alignment identifier being disposed on the substrate;

forming a color filter layer on a side of the exposure alignment identifier away from the substrate, the color filter layer includes an identification thickened layer covering the exposure alignment identifier, and the identification thickened layer has a same shape and a same size as the exposure alignment identifier;

forming a black photoresist layer on a side of the color filter layer away from the substrate; and,

forming a black light shielding layer by exposing the black photoresist layer by aligning the exposure alignment identifier and the identification thickened layer.

The embodiments of the present disclosure further provide a method for manufacturing a display panel, and the method includes:

providing a substrate, at least one exposure alignment identifier being disposed on the substrate;

forming a first color resist layer on a side of the exposure alignment identifier away from the substrate, and patterning the first color resist layer to form a first color filter layer and a first identification layer covering the exposure alignment identifier;

forming a second color resist layer on a side of the first color filter layer away from the substrate, and patterning the second color resist layer to form a second color filter layer and a second identification layer covering the first identification layer;

forming a third color resist layer on a side of the second color filter layer away from the substrate, and patterning the third color resist layer to form a third color filter layer and a third identification layer covering the second identification layer; the first identification layer, the second identification layer, and the third identification layer constitute an identification thickened layer covering the exposure alignment identifier, and the identification thickened layer has a same shape and a same size as the exposure alignment identifier;

forming a black photoresist layer on a side of the third color filter layer away from the substrate; and,

forming a black light shielding layer by exposing the black photoresist layer by aligning the exposure alignment identifier, a position of the exposure alignment identifier is determined by detecting outlines of the exposure alignment identifier and the identification thickened layer.

In the method for manufacturing the display panel according to the embodiments of the present disclosure, the thickness of the position where the exposure alignment identifier is located is increased, by the color filter layer being formed on the side of the exposure alignment identifier away from the substrate. The color filter layer includes the identification thickened layer, the identification thickened layer covers the exposure alignment identifier, and the identification thickened layer has the same shape and the same size as the exposure alignment identifier. The thickness of the position where the exposure alignment identifier is located is further increased, by the black photoresist layer being formed on the side of the color filter layer away from the substrate, thus an accurate recognition of the exposure alignment identifier may be realized.

The embodiments of the present disclosure further provide a display panel, and the display panel includes:

a color film substrate;

an array substrate, disposed opposite to the color film substrate;

a liquid crystal layer, filled between the color film substrate and the array substrate; manufacturing of the color film substrate includes the following steps:

providing a substrate, at least one exposure alignment identifier being disposed on the substrate;

forming a color filter layer on a side of the exposure alignment identifier away from the substrate, the color filter layer includes an identification thickened layer covering the exposure alignment identifier, and the identification thickened layer has a same shape and a same size as the exposure alignment identifier;

forming a black photoresist layer on a side of the color filter layer away from the substrate; and,

forming a black light shielding layer by exposing the black photoresist layer by aligning the exposure alignment identifier and the identification thickened layer.

### BRIEF DESCRIPTION OF THE DRAWINGS

In order to more clearly illustrate the embodiments of the present disclosure or the technical solutions in the prior art, the drawings to be used in the description of the embodiments or the prior art will be briefly described below. Obviously, the drawings in the following description are only certain embodiments of the present disclosure, and other drawings may be obtained according to the structures shown in the drawings without any creative work for those skilled in the art.

FIG. 1 is a schematic flow chart of a method for manufacturing a display panel according to the embodiments of the present disclosure;

FIG. 2 is a schematic structural diagram of a substrate according to the embodiments of the present disclosure;

FIG. 3 is a schematic structural diagram of the display panel after forming a color filter layer;

FIG. 4 is a schematic structural diagram of the display panel after forming a black photoresist layer;

FIG. 5 is a schematic plan view of the display panel after forming the black photoresist layer;

FIG. 6 is a schematic structural diagram of the display panel after forming a black light shielding layer;

FIG. 7 is a schematic structural diagram of the display panel with a single identification thickened layer according to the embodiments of the present disclosure;

FIG. 8 is a schematic structural diagram of the display panel with double identification thickened layers according to the embodiments of the present disclosure;

FIG. 9 is a schematic flow chart of forming a color filter layer according to the embodiments of the present disclosure;

FIG. 10 is a schematic structural diagram of the display panel after forming a first color resist layer;

FIG. 11 is a schematic structural diagram of the display panel after patterning the first color resist layer;

FIG. 12 is a schematic structural diagram of the display panel after forming a second color resist layer;

FIG. 13 is a schematic structural diagram of the display panel after patterning the second color resist layer;

FIG. 14 is a schematic structural diagram of the display panel after forming a third color resist layer;

FIG. 15 is a schematic structural diagram of the display panel after patterning the third color resist layer;

FIG. 16 is another schematic structural diagram of the display panel after forming a black photoresist layer;

FIG. 17 is another schematic structural diagram of the display panel after patterning the black photoresist layer.

### DETAILED DESCRIPTION OF THE EMBODIMENTS

In order to clarify the purposes, technical solutions and advantages of the present disclosure, the technical solutions of the present disclosure will be clearly and completely described by the embodiments with reference to the drawings in the embodiments of the present disclosure. Obviously, the described embodiments are only a part of the embodiments of the present disclosure, not all of the embodiments. All other embodiments obtained by those of ordinary skill in the art without creative labor based on the embodiments here are within the scope of protection in the present disclosure.

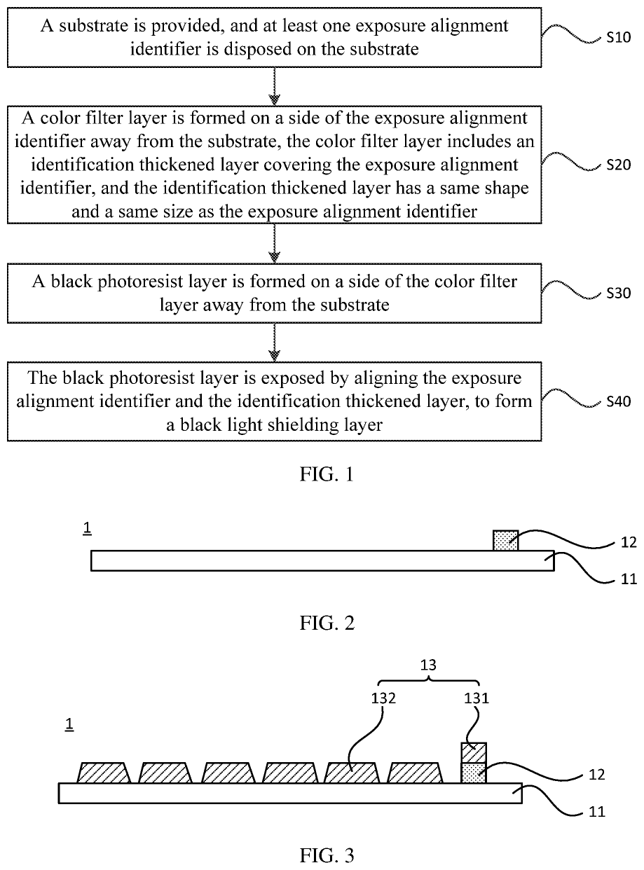

FIG. 1 is a schematic flow chart of a method for manufacturing a display panel according to the embodiments of the present disclosure. Referring to FIG. 1, the method includes:

S10, a substrate is provided, and at least one exposure alignment identifier is disposed on the substrate.

The substrate includes a display area and a non-display area located on at least one side of the display area, and at least one exposure alignment identifier is located in the non-display area of the substrate.

Optionally, FIG. 2 is a schematic structural diagram of the substrate according to the embodiments of the present disclosure. FIG. 2 shows only one of the exposure alignment identifiers 12 disposed on the substrate 11, but it is not a limit to the method of manufacturing the display panel of the present embodiments. In other embodiments, the number of the exposure alignment identifiers 12 may be multiple based on actual needs.

S20, a color filter layer is formed on a side of the exposure alignment identifier away from the substrate, the color filter layer includes an identification thickened layer covering the exposure alignment identifier, and the identification thickened layer has a same shape and a same size as the exposure alignment identifier.

The color filter layer may be color filter units of a plurality of colors. The thickness of the color filter layer may be set by needs, which is not specifically limited in the present embodiments.

Optionally, FIG. 3 is a schematic structural diagram of a display panel after forming a color filter layer. Referring to FIG. 3, the color filter layer 13 includes an identification thickened layer 131 and a plurality of color filter units 132, the identification thickened layer 131 covers the exposure alignment identifier 12, and the identification thickened layer has the same shape and the same size as the exposure alignment identifier 12. Thus, the thickness of the position where the exposure alignment identifier 12 is located is increased to a total thickness of the single exposure alignment identifier 12 and the identification thickened layer 131, thereby the identifiability of the exposure alignment identifier 12 is improved.

Optionally, the shape of the exposure alignment identifier 12 is a square, of which the side length is 300 um, then the shape of the identification thickened layer 131 is a square, of which the side length is 300 um, and the vertical projection of the identification thickened layer 131 on the substrate 11 coincides with the vertical projection of the exposure alignment identifier 12 on the substrate 11. Alternatively, the thickness of the exposure alignment identifier 12 is 0.5 um, and the thickness of the identification thickened layer 131 is 2.0 um, then the height of the position where the exposure alignment identifier 12 is located is increased from 0.5 um to 2.5 um. The height thereof is increased, thereby the identifiability is improved.

S30, a black photoresist layer is formed on a side of the color filter layer away from the substrate.

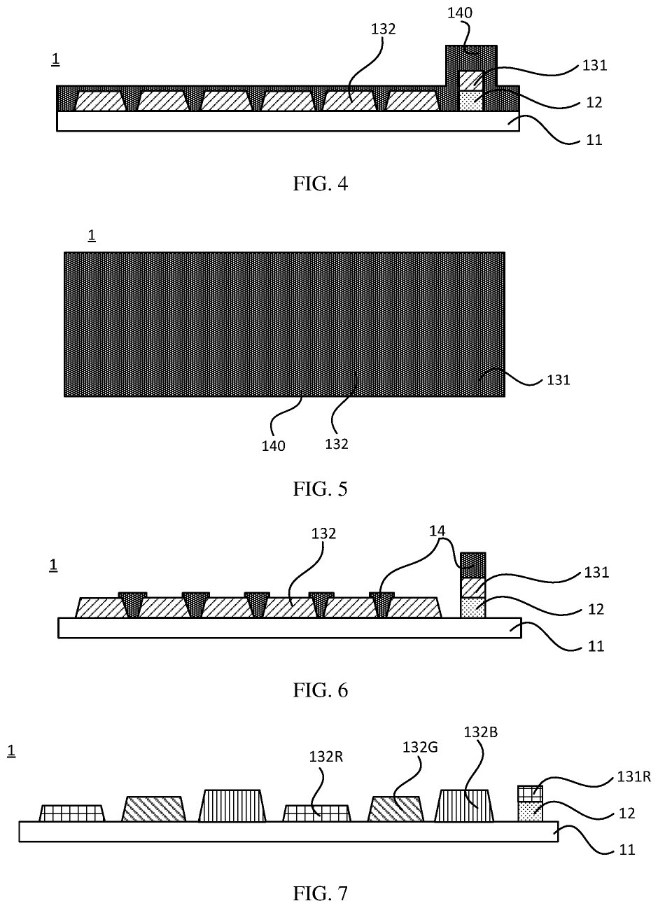

Optionally, FIG. 4 is a schematic structural diagram of the display panel after forming a black photoresist layer; FIG. 5 is a schematic plan view of the display panel after forming the black photoresist layer. Referring to FIGS. 4 and 5, the black photoresist layer 140 covers the identification thickened layer 131 and the color filter units 132.

It should be noted that FIG. 5 shows only the color filter units 132 of 4 rows and 6 columns, which is not a limitation of the present disclosure. In other embodiments, the number of rows and columns of the color filter units 132 may be set according to actual needs of the display panel.

S40, the black photoresist layer is exposed by aligning the exposure alignment identifier and the identification thickened layer, to form a black light shielding layer.

In the alignment process, the height difference between the position of the exposure alignment identifier and the peripheral area is a total of the thicknesses of the exposure alignment identifier and the identification thickened layer. The height difference from the peripheral area is large, so that the position of the exposure alignment identifier may be determined by detecting the thickness of the display panel, or detecting the height of the surface of the black photoresist layer away from the substrate, which improves the accuracy of position recognition of the exposure alignment identifier and the accuracy of exposure alignment, thereby improving the accuracy of manufacturing of the black light shielding layer.

Optionally, FIG. 6 is a schematic structural diagram of the display panel after forming a black light shielding layer. Referring to FIG. 6, the precise exposure of the black photoresist layer may be achieved by accurately identifying the exposure alignment identifier 12, thereby making the position distribution of the black light shielding layer 14 and the color filter units 132 on the substrate more precise, and improving the picture display quality of the display panel.

It should be noted that FIG. 6 shows only the relative positional relationship between the color filter layer and the black light shielding layer, and the relative sizes of the color filter layer and the black light shielding layer are not specifically limited.

In the method for manufacturing the display panel according to the embodiments of the present disclosure, the thickness of the position where the exposure alignment identifier is located is increased by forming the color filter layer on the side of the exposure alignment identifier away from the substrate. The color filter layer includes the identification thickened layer, the identification thickened layer covers the exposure alignment identifier, and the identification thickened layer has the same shape and the same size as the exposure alignment identifier. The thickness of the position where the exposure alignment identifier is located is further increased by forming the black photoresist layer on the side of the color filter layer away from the substrate, thus the accurate recognition of the exposure alignment identifier may be realized.

FIG. 7 is a schematic structural diagram of the display panel with the identification thickened layer as a single layer according to the embodiments of the present disclosure. Referring to FIG. 7, alternatively, the color filter layer further includes a first color filter layer 132R, a second color filter layer 132G, and a third color filter layer 132B; vertical projections of the first color filter layer 132R, the second color filter 132G, and the third color filter layer 132B on the substrate 11 are non-overlapping.

The first color filter layer 132R includes a plurality of first color filter units, the second color filter layer 132G includes a plurality of second color filter units, and the third color filter layer 132B includes a plurality of third color filter units.

Optionally, the identification thickened layer 131 is formed in a same process as any one of the first color filter layer 132R, the second color filter layer 132G, and the third color filter layer 132B.

Referring to FIG. 7, the identification thickened layer 131R is formed in a same process as the first color filter layer 132R. In this case, the added height difference of the position where the exposure alignment identifier 12 is located is the same as the thickness of the first color filter layer 132R, which improves the accuracy of recognition of the exposure alignment identifier, thereby improving the accuracy of manufacturing of the black light shielding layer.

It should be noted that FIG. 7 shows only the structure of the display panel of which the identification thickened layer is formed in a same process as the first color filter layer, which is not a limitation to the present disclosure. In other embodiments, the identification thickened layer may also be formed in a same process as the second color filter layer, or the third color filter layer.

Optionally, the identification thickened layer includes a first identification layer and a second identification layer, the second identification layer is located on a side of the first identification layer away from the exposure alignment identifier. The first identification layer is formed in a same process as the first color filter layer, and the second identification layer is formed in a same process as the second color filter layer; or, the first identification layer is formed in a same process as the second color filter layer, and the second identification layer is formed in a same process as the third color filter layer; or, the first identification layer is formed in a same process as the first color filter layer, and the second identification layer is formed in a same process as the third color filter layer.

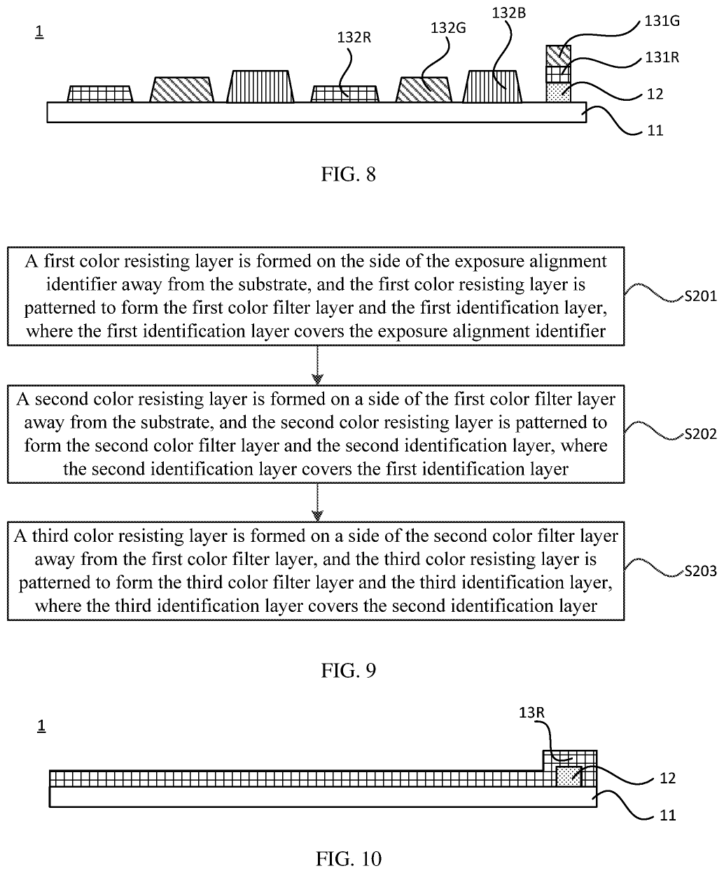

Optionally, FIG. 8 is a schematic structural diagram of the display panel with double identification thickened layers according to the embodiments of the present disclosure. Referring to FIG. 8, the identification thickened layer includes a first identification layer 131R and a second identification layer 131G. The first identification layer 131R is formed in a same process as the first color filter layer 132R, and the second identification layer 131G is formed in a same process as the second color filter 132G. In this case, the added height difference of the position where the exposure alignment identifier 12 is located is equal to a total thicknesses of the first color filter layer 132R and the second color filter layer 132G, making the height difference between the position where the exposure alignment identifier 12 is located and the peripheral position further increase, which further improves the accuracy of recognition of the exposure alignment identifier, thereby further improving the accuracy of manufacturing of the black light shielding layer.

It should be noted that FIG. 8 shows only the structure of the display panel of which the identification thickened layer is formed in a same process as the first color filter layer and the second color filter layer, which is not a limit to the present disclosure. In other embodiments, the identification thickened layer may also be formed in a same process as any two of the three color filter layers.

Optionally, the identification thickened layer includes a first identification layer, a second identification layer and a third identification layer which are arranged in a stack. The second identification layer is located on a side of the first identification layer away from the exposure alignment identifier. The first identification layer is formed in a same process as the first color filter layer, the second identification layer is formed in a same process as the second color filter layer, and the third identification layer is formed in a same process as the third color filter layer.

Thus, the identification thickened layer may be formed in a same process as any one, any two, or all three of the first color filter layer, the second color filter layer, and the third color filter layer, namely the formation of the identification thickened layer eliminates the need to introduce new process, which simplifies the process and saves on process costs.

Optionally, take the identification thickened layer including three-layer films as an example to illustrate the forming of the color filter layer. FIG. 9 is a schematic flow chart of forming the color filter layer according to the embodiments of the present disclosure. Referring to FIG. 9, the steps include:

S201, a first color resist layer is formed on the side of the exposure alignment identifier away from the substrate, and the first color resist layer is patterned to form the first color filter layer and the first identification layer, where the first identification layer covers the exposure alignment identifier.

The thickness of the first identification layer may be controlled by adjusting the exposure condition. Alternatively, during exposure, the greater the light intensity and the longer the exposure time is, the thinner the thickness of the first identification layer is; conversely, the smaller the light intensity and the shorter the exposure time is, the thicker the thickness of the first identification layer is.

Optionally, FIG. 10 is a schematic structural diagram of the display panel after forming the first color resist layer. Referring to FIG. 10, the first color resist layer 13R covers the exposure alignment identifier 12 and the substrate 11.

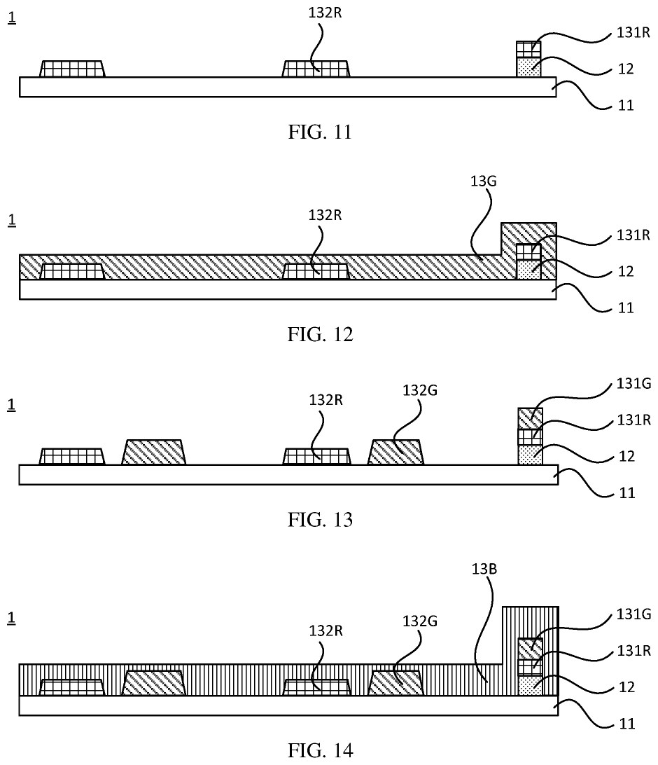

Optionally, FIG. 11 is a schematic structural diagram of the display panel after patterning the first color resist layer. Referring to FIGS. 10 and 11, the first color filter layer 132R and the first identification layer 131R are formed after patterning the first color resist layer 13R, and the first identification layer 131R has the same shape and the same size as the exposure alignment identifier 12.

S202, a second color resist layer is formed on a side of the first color filter layer away from the substrate, and the second color resist layer is patterned to form the second color filter layer and the second identification layer, where the second identification layer covers the first identification layer.

The thickness of the second identification layer may also be controlled by adjusting the exposure conditions, which may refer to that of the first identification layer, details are not described herein.

Optionally, FIG. 12 is a schematic structural diagram of the display panel after forming the second color resist layer. Referring to FIG. 12, the second color resist layer 13G covers the first color filter layer 132R, the first identification layer 131R, and the substrate 11.

Optionally, FIG. 13 is a schematic structural diagram of the display panel after patterning the second color resist layer. Referring to FIGS. 12 and 13, the second color filter layer 132G and the second identification layer 131G are formed after patterning the second color resist layer 13G, and the second identification layer 131G has the same shape and the same size as the first identification layer 131R and the exposure alignment identifier 12.

S203, a third color resist layer is formed on a side of the second color filter layer away from the first color filter layer, and the third color resist layer is patterned to form the third color filter layer and the third identification layer, where the third identification layer covers the second identification layer.

The thickness of the third identification layer may also be controlled by adjusting the exposure conditions, which may refer to that of the first identification layer, details are not described herein.

Optionally, FIG. 14 is a schematic structural diagram of the display panel after forming the third color resist layer. Referring to FIG. 14, the third color resist layer 13B covers the first color filter layer 132R, the second color filter layer 132G, the second identification layer 131G, and the substrate 11.

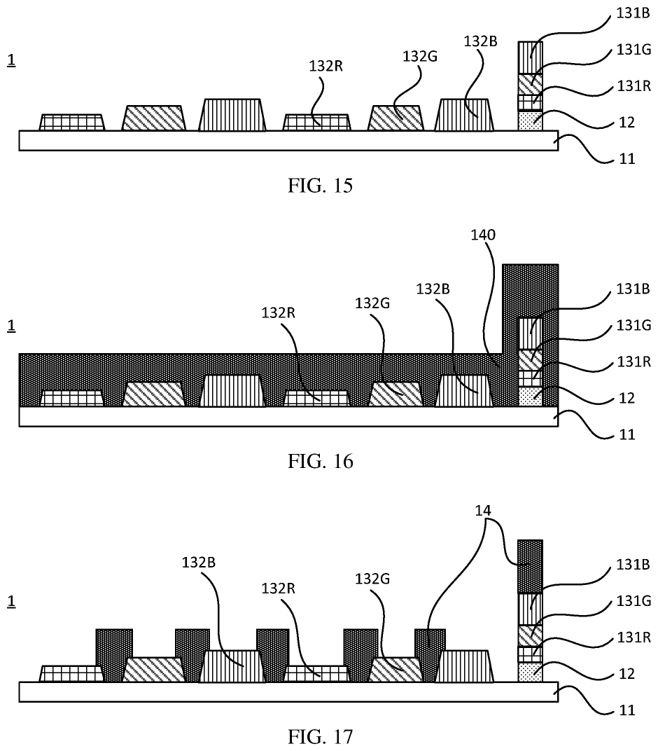

Optionally, FIG. 15 is a schematic structural diagram of the display panel after patterning the third color resist layer. Referring to FIGS. 14 and 15, the third color filter layer 132B and the third identification layer 131B are formed after patterning the third color resist layer 13B, and the third identification layer 131B has the same shape and the same size as the first identification layer 131R, the second identification layer 131G, and the exposure alignment identifier 12.

Optionally, FIG. 16 is another schematic structural diagram of the display panel after forming the black photoresist layer. Referring to FIG. 16, the black photoresist layer 140 covers the first color filter layer 132R, the second color filter layer 132G, the third color filter layer 132B, the third identification layer 131B, and the substrate 11. In this case, the height difference between the height of the black photoresist layer 140 at the position where the alignment identifier 12 is located and the peripheral area is a total of the thicknesses of the exposure alignment identifier 12, the first identification layer 131R, the second identification layer 131G, and the third identification layer 131B. The total thicknesses of the film layers is significantly increased relative to the thickness of the exposure alignment identifier 12 itself, which facilitates the accurate recognition of the exposure alignment identifier, thereby making the exposure alignment of the black photoresist layer more precise.

Meanwhile, vertical projections of the first color filter layer 132R, the second color filter layer 132G, and the third color filter layer 132B on the substrate 11 are non-overlapping, thus forming the color filter layer in the display panel.

Optionally, FIG. 17 is another schematic structural diagram of the display panel after patterning the black photoresist layer. Referring to FIGS. 16 and 17, the black light shielding layer 14 is formed after patterning the black photoresist layer 140.

Optionally, a shape of the exposure alignment identifier may be a rectangle, a cross, a rhombus, or a circle. The embodiments of the present disclosure are not limited to these, as long as the precise alignment before exposure can be achieved.

Optionally, when the shape of the exposure alignment identifier is a rectangle, the shape of the identification thickened layer is a rectangle as well; when the shape of the exposure alignment identifier is a cross, the shape of the identification thickened layer is a cross as well. It should be noted that FIG. 5 only shows the shape of the exposure alignment identifier being a circle, which is only a description of the present disclosure, and is not limited thereto.

Optionally, step S40 in FIG. 1 includes: outlines of the exposure alignment identifier and the identification thickened layer are detected to determine the position of the exposure alignment identifier, and the exposure alignment identifier and the identification thickened layer are aligned according to the position of the exposure alignment identifier.

Before the exposure alignment, the black photoresist layer is fully covered on the substrate and the structure formed by the foregoing processes. Since the OD of the black photoresist layer is high, of which the light absorption capability is strong, therefore, if the optical registration method is used to identify the exposure alignment identifier, it is easy to cause inaccurate identification of the exposure alignment identifier, which may result in inaccurate alignment of the exposure machine. Therefore, according to the embodiments of the present disclosure, the outlines of the exposure alignment identifier and the identification thickened layer covering on the exposure alignment identifier are detected, by the height difference between the height of the position where the exposure alignment identifier is located and the peripheral area, to determine the position of the exposure alignment identifier, which may achieve accurate identification of the exposure alignment identifier, thereby achieving accurate exposure of the black photoresist layer.

Optionally, the substrate is an array substrate. The array substrate may include a plurality of arrayed pixel units, a plurality of scan lines, and a plurality of data lines.

The display panel according to the embodiments of the present disclosure integrates the color filter layer and the black light shielding layer onto the array substrate. The capacitive coupling effect between the pixel electrode and the metal trace may be reduced by increasing the distance between them through the color filter layer, which may improve the signal delay effect on the metal trace, thereby improving the picture display quality of the display panel. Moreover, the black light shielding layer and the color filter layer are integrated on the array substrate, which may solve the incomplete shading problem caused by the black light shielding layer formed on the opposite substrate, thereby improving the picture display quality of the display panel.

Optionally, the first color filter layer is a red filter layer, the second color filter layer is a green filter layer, and the third color filter layer is a blue filter layer.

Optionally, for the liquid crystal display panel, the pixel units may emit red, green, or blue lights by configuring the filter layers of different colors, thereby realizing the normal display of the color picture of the display panel.

Optionally, the black light shielding layer is a black matrix or a black spacer.

The black matrix is mainly used to prevent light leakage between pixels, and increase the contrast of colors to ensure the picture display effect of the display panel. The black spacer is a support disposed between the array substrate and the opposite substrate, which is configured to support the opposite substrate and the array substrate with a certain light shielding effect.

In the method for manufacturing the display panel according to the embodiment of the present disclosure, the thickness of the position where the exposure alignment identifiers are located is increased by forming the color filter layer on the side of the exposure alignment identifier away from the substrate. The color filter layer includes the identification thickened layer, the identification thickened layer covers the exposure alignment identifier, and the identification thickened layer has the same shape and the same size as the exposure alignment identifier. The thickness of the position where the exposure alignment identifier is located is further increased, when the black photoresist layer is formed on the side of the color filter layer away from the substrate, thus the accurate recognition of the exposure alignment identifier may be realized. Moreover, the color filter layer and the black light shielding layer are integrated on the array substrate, which may solve the incomplete shading problem which is caused due to the black light shielding layer formed on the opposite substrate, improve the signal delay effect on the metal trace, and improve the picture display quality of the display panel.

The present disclosure further provides a display panel, and the display panel includes:

a color film substrate;

an array substrate, disposed opposite to the color film substrate;

a liquid crystal layer, filled between the color film substrate and the array substrate. Manufacturing of the color film substrate includes the following steps:
a substrate is provided, and at least one exposure alignment identifier is disposed on the substrate;
a color filter layer is formed on a side of the exposure alignment identifier away from the substrate, the color filter layer includes an identification thickened layer covering the exposure alignment identifier, and the identification thickened layer has a same shape and a same size as the exposure alignment identifier;
a black photoresist layer is formed on a side of the color filter layer away from the substrate; and,
the black photoresist layer is exposed by aligning the exposure alignment identifier and the identification thickened layer, to form a black light shielding layer.

The manufacturing method of the color film substrate is the embodiments of the method of manufacturing the display panel in the above embodiments. In the alignment process of the present disclosure, the height difference between the position of the exposure alignment identifier and the peripheral area is a total of the thicknesses of the exposure alignment identifier and the identification thickened layer. The height difference from the peripheral area is large, so that the position of the exposure alignment identifier may be determined by detecting the thickness of the display panel, or detecting the height of the surface of the black photoresist layer away from the substrate, which improves the accuracy of position recognition of the exposure alignment identifier and the accuracy of exposure alignment, thereby improving the accuracy of manufacturing of the black light shielding layer.

It should be noted that the above are only optional embodiments of the present disclosure and the technical principles applied thereto. Those skilled in the art will understand that the present disclosure is not limited to the specific embodiments described herein, and that various modifications, re-adjustments, combinations and substitutions may be made without departing from the scope of the disclosure. Therefore, although the present disclosure has been described in detail by the above embodiments, the present disclosure is not limited to the above embodiments, and other equivalent embodiments may be included without departing from the concept of the present disclosure. The scope of the present disclosure is determined by the scope of the appended claims.

What is claimed is:

1. A method for manufacturing a display panel, wherein the method comprises:
providing a substrate, at least one exposure alignment identifier being disposed on the substrate;
forming a color filter layer on a side of the exposure alignment identifier away from the substrate, the color filter layer comprising an identification thickened layer covering the exposure alignment identifier, the identification thickened layer having a same shape and a same size as the exposure alignment identifier;
forming a black photoresist layer on a side of the color filter layer away from the substrate; and,
forming a black light shielding layer by exposing the black photoresist layer by aligning the exposure alignment identifier and the identification thickened layer.

2. The method of claim 1, wherein,
the color filter layer further comprises a first color filter layer, a second color filter layer, and a third color filter layer; vertical projections of the first color filter layer, the second color filter layer, and the third color filter layer on the substrate are non-overlapping.

3. The method of claim 2, wherein,
the identification thickened layer is formed in the same process as any one of the first color filter layer, the second color filter layer, and the third color filter layer; or,
the identification thickened layer comprises a first identification layer and a second identification layer, the second identification layer being located on a side of the first identification layer away from the exposure alignment identifier; the first identification layer is formed in a same process as the first color filter layer, and the second identification layer is formed in a same process as the second color filter layer; or, the first identification layer is formed in a same process as the second color filter layer, and the second identification layer is formed in a same process as the third color filter layer; or, the first identification layer is formed in a same process as the first color filter layer, and the second identification layer is formed in a same process as the third color filter layer; or,
the identification thickened layer comprises a first identification layer, a second identification layer, and a third identification layer arranged in stack, the second identification layer being located on a side of the first identification layer away from the exposure alignment identifier; the first identification layer is formed in a same process as the first color filter layer, and the second identification layer is formed in a same process as the second color filter layer, and the third identification layer is formed in a same process as the third color filter layer.

4. The method of claim 3, wherein, forming the color filter layer on the side of the exposure alignment identifier away from the substrate comprises:
forming a first color resist layer on the side of the exposure alignment identifier away from the substrate, patterning the first color resist layer to form the first color filter layer and the first identification layer, the first identification layer covering the exposure alignment identifier;
forming a second color resist layer on a side of the first color filter layer away from the substrate, patterning the second color resist layer to form the second color filter layer and the second identification layer, the second identification layer covering the first identification layer; and,
forming a third color resist layer on a side of the second color filter layer away from the first color filter layer, patterning the third color resist layer to form the third color filter layer and the third identification layer, the third identification layer covering the second identification layer.

5. The method of claim 2, wherein, aligning the exposure alignment identifier and the identification thickened layer comprises:
detecting outlines of the exposure alignment identifier and the identification thickened layer to determine a position of the exposure alignment identifier, aligning the exposure alignment identifier and the identification thickened layer according to the position of the exposure alignment identifier.

6. The method of claim 1, wherein, a shape of the exposure alignment identifier is a rectangular, a cross, a rhombus, or a circle.

7. The method of claim 1, wherein, aligning the exposure alignment identifier and the identification thickened layer comprises:
detecting outlines of the exposure alignment identifier and the identification thickened layer to determine a position of the exposure alignment identifier, aligning the exposure alignment identifier and the identification thickened layer according to the position of the exposure alignment identifier.

8. The method of claim 1, wherein the substrate is an array substrate.

9. The method of claim 2, wherein,
the first color filter layer is a red filter layer, the second color filter layer being a green filter layer, the third color filter layer being a blue filter layer.

10. The method of claim 1, wherein the black light shielding layer is a black matrix or a black spacer.

11. A method for manufacturing a display panel, wherein the method comprises:
providing a substrate, at least one exposure alignment identifier being disposed on the substrate;
forming a first color resist layer on a side of the exposure alignment identifier away from the substrate, patterning the first color resist layer to form a first color filter layer and a first identification layer, the first identification layer covering the exposure alignment identifier;
forming a second color resist layer on a side of the first color filter layer away from the substrate, patterning the second color resist layer to form a second color filter layer and a second identification layer, the second identification layer covering the first identification layer;
forming a third color resist layer on a side of the second color filter layer away from the substrate, patterning the third color resist layer to form a third color filter layer and a third identification layer, the third identification layer covering the second identification layer; wherein, the first identification layer, the second identification layer, and the third identification layer constitute an identification thickened layer, the identification thickened layer covering the exposure alignment identifier, the identification thickened layer having a same shape and a same size as the exposure alignment identifier;
forming a black photoresist layer on a side of the third color filter layer away from the substrate; and,
detecting outlines of the exposure alignment identifier and the identification thickened layer to determine a position of the exposure alignment identifier, aligning the exposure alignment identifier and the identification thickened layer according to the position of the exposure alignment identifier to expose the black photoresist layer and forming a black light shielding layer.

12. The method of claim 11, wherein, a shape of the exposure alignment identifier is a rectangular, a cross, a rhombus, or a circle.

13. The method of claim 11, wherein the substrate is an array substrate.

14. The method of claim 11, wherein, the first color filter layer is a red filter layer, the second color filter layer being a blue filter layer, the third color filter layer being a blue filter layer.

15. The method of claim 11, wherein the black light shielding layer is a black matrix or a black spacer.

16. The method of claim 11, wherein, the identification thickened layer is formed in the same process as any one of the first color filter layer, the second color filter layer, and the third color filter layer; or,
the identification thickened layer comprises a first identification layer and a second identification layer, the second identification layer being located on a side of the first identification layer away from the exposure alignment identifier; the first identification layer is formed in a same process as the first color filter layer, and the second identification layer is formed in a same process as the second color filter layer; or, the first identification layer is formed in a same process as the second color filter layer, and the second identification layer is formed in a same process as the third color filter layer; or, the first identification layer is formed in a same process as the first color filter layer, and the second identification layer is formed in a same process as the third color filter layer; or,
the identification thickened layer comprises a first identification layer, a second identification layer, and a third identification layer arranged in stack, the second identification layer being located on a side of the first identification layer away from the exposure alignment identifier; the first identification layer is formed in a same process as the first color filter layer, and the second identification layer is formed in a same process as the second color filter layer, and the third identification layer is formed in a same process as the third color filter layer.

17. A display panel, wherein, the display panel comprises:
a color film substrate;
an array substrate, disposed opposite to the color film substrate;
a liquid crystal layer, filled between the color film substrate and the array substrate; wherein, manufacturing of the color film substrate comprises the following steps:
providing a substrate, at least one exposure alignment identifier being disposed on the substrate;
forming a color filter layer on a side of the exposure alignment identifier away from the substrate, the color filter layer comprising an identification thickened layer, the identification thickened layer covering the exposure alignment identifier, the identification thickened layer having a same shape and a same size as the exposure alignment identifier;
forming a black photoresist layer on a side of the color filter layer away from the substrate; and,
forming a black light shielding layer by exposing the black photoresist layer by aligning the exposure alignment identifier and the identification thickened layer.

18. The display panel of claim 17, wherein, the color filter layer further comprises a first color filter layer, a second color filter layer, and a third color filter layer, vertical projections of the first color filter layer, the second color filter layer, and the third color filter layer on the substrate being non-overlapping.

19. The display panel of claim 18, wherein, the identification thickened layer is formed in the same process as any one of the first color filter layer, the second color filter layer, and the third color filter layer; or,
the identification thickened layer comprises a first identification layer and a second identification layer, the second identification layer being located on a side of the first identification layer away from the exposure alignment identifier; the first identification layer is formed in a same process as the first color filter layer, and the second identification layer is formed in a same process as the second color filter layer; or, the first identification layer is formed in a same process as the second color filter layer, and the second identification layer is formed in a same process as the third color filter layer; or, the first identification layer is formed in a same process as the first color filter layer, and the second identification layer is formed in a same process as the third color filter layer; or,
the identification thickened layer comprises a first identification layer, a second identification layer, and a third identification layer arranged in stack, the second identification layer being located on a side of the first identification layer away from the exposure alignment identifier; the first identification layer is formed in a same process as the first color filter layer, and the second identification layer is formed in a same process as the second color filter layer, and the third identification layer is formed in a same process as the third color filter layer.

20. The display panel of claim 19, wherein, forming a color filter layer on the side of the exposure alignment identifier away from the substrate comprises:
forming a first color resist layer on the side of the exposure alignment identifier away from the substrate, patterning the first color resist layer to form the first color filter layer and the first identification layer, the first identification layer covering the exposure alignment identifier;
forming a second color resist layer on a side of the first color filter layer away from the substrate, patterning the second color resist layer to form the second color filter layer and the second identification layer, the second identification layer covering the first identification layer; and,
forming a third color resist layer on a side of the second color filter layer away from the first color filter layer, patterning the third color resist layer to form the third color filter layer and the third identification layer, the third identification layer covering the second identification layer.
